(19) United States
(12) Patent Application Publication
(10) Pub. No.: US 2024/0030686 A1
(43) Pub. Date: Jan. 25, 2024

(54) Light-Emitting Semiconductor Chip and Method for Manufacturing Light-Emitting Semiconductor Chip

(71) Applicant: ams-OSRAM International GmbH, Regensburg (DE)

(72) Inventors: Lars Nähle, Bad Abbach (DE); Christoph Eichler, Donaustauf (DE)

(21) Appl. No.: 18/255,941

(22) PCT Filed: Dec. 9, 2021
(86) PCT No.: PCT/EP2021/084996

§ 371 Date: Jun. 5, 2023

(30) Foreign Application Priority Data
Dec. 11, 2020 (DE) 102020133177.0

(51) Int. Cl. H01S 5/40; H01S 5/026; H01S 5/10

(52) U.S. Cl. CPC H01S 5/4031; H01S 5/4087; H01S 5/0265; H01S 5/101; H01S 5/1021; H01S 5/22

(57) ABSTRACT

In an embodiment a light-emitting semiconductor chip includes a semiconductor body having a plurality of emitter units, wherein each emitter unit has an active region which is arranged in a resonator having an outcoupling side and a rear side and which is configured to emit light at the outcoupling side along a radiation emission direction, wherein, in each emitter unit, the active region is completely penetrated by at least one recess in the semiconductor body, wherein, in each emitter unit, in a region of the active region the recess has a recess width measured along the radiation emission direction, and wherein recess widths of the emitter units are at least partially different.

### CROSS-REFERENCE TO RELATED APPLICATIONS

This patent application is a national phase filing under section 371 of PCT/EP2021/084996, filed Dec. 9, 2021, which claims the priority of German patent application 102020133177.0, filed Dec. 11, 2020, each of which is incorporated herein by reference in its entirety.

### TECHNICAL FIELD

A light-emitting semiconductor chip and a method for manufacturing a light-emitting semiconductor chip are specified.

### BACKGROUND

Laser light sources are often used in optical devices such as projectors, so-called VR and/or AR glasses (VR: “virtual reality”; AR: “augmented reality”, etc.). However, due to the physical nature of coherent laser radiation, certain image artifacts such as interference and/or light granulation known as speckles or the like may occur, which are undesirable in many applications. In order to improve the image quality in this respect, it can be helpful to work with multiple-emitter devices, which, in the optimum case, have emission wavelengths that are shifted relative to one another. Particularly advantageous here can be devices with 2, 3, 4 or more emitters whose emission wavelengths are shifted relative to one another in a defined manner.

Changes in wavelength can be achieved by varying the laser geometry such as ridge width, resonator length and/or mirroring. However, these wavelength changes are usually accompanied by a change in laser parameters such as threshold, slope and operation current, which is undesirable since all emitters on a chip should have comparable laser parameters. Multiple-epitaxy can also be used to produce emitters with different wavelengths. However, this requires a high technical effort and is expensive. The epitaxy can also be influenced by strain-changing structures on the wafer in such a way that locally different wavelengths are formed. However, these structures require additional space on the chip, which is expensive, and can have undesirable side effects on laser parameters such as the far-field width.

The approaches chosen so far, for example a variation of the optical waveguide geometry parameters and/or the mirroring, are thus technically very difficult to implement in some cases and inevitably lead to a variation of the operating parameters with the emission wavelength, whereas a retention of comparable operating parameters would be desirable.

### SUMMARY

Embodiments provide a light-emitting semiconductor chip. Further embodiments provide a method for manufacturing a light-emitting semiconductor chip.

According to at least one embodiment, a light-emitting semiconductor chip comprises a semiconductor body having at least one emitter unit. Preferably, the light-emitting semiconductor chip comprises a plurality of emitter units, for example greater than or equal to 2 or greater than or equal to 3 or greater than or equal to 4 emitter units. Particularly preferably, the emitter units may be of the same or at least similar design, unless otherwise described. Particularly preferably, the plurality of emitter units is monolithically formed in the semiconductor body. In a method for manufacturing the light-emitting semiconductor chip, the semiconductor body is grown, for example on a substrate, the semiconductor body comprising the one or the plurality of emitter units. Unless otherwise specified, the features described below apply equally to a light-emitting semiconductor chip having one emitter unit and also to a light-emitting semiconductor chip having a plurality of emitter units. Furthermore, the following description applies equally to the light-emitting semiconductor chip as well as to the method for manufacturing the light-emitting semiconductor chip.

Each of the at least one emitter unit has an active region that is configured and intended to generate light during operation. Light may refer here and hereinafter in particular to electromagnetic radiation having one or more spectral components in an infrared to ultraviolet wavelength range. Accordingly, the terms light, radiation and electromagnetic radiation may be used interchangeably. The light generated in the active region may be specified by a characteristic wavelength. In this context, the characteristic wavelength may denote the wavelength of the spectrum of the generated light with the highest intensity. Alternatively, the characteristic wavelength may denote the average wavelength of the spectral range in which the generated light lies. Furthermore, the characteristic wavelength can also denote the average wavelength of the spectrum of the generated light weighted over the individual spectral intensities.

Furthermore, the active region of each of the at least one emitter unit is arranged in a resonator. The resonator is configured in particular to amplify the light generated in the active region. For example, the resonator can define a radiation emission direction along which light is emitted by an emitter unit during operation.

The semiconductor body can be manufactured as a semiconductor layer sequence based on different semiconductor material systems depending on the wavelength. For long-wave, infrared to red radiation, for example, a semiconductor layer sequence based on InₓGa_{y}Al_{1-x-y}As, for red to yellow radiation, for example, a semiconductor layer sequence based on InₓGa_{y}Al_{1-x-y}P and for short-wave visible, i.e. in particular in the range from green to blue light, and/or for UV radiation for example a semiconductor layer sequence based on InₓGa_{y}Al_{1-x-y}N is suitable, wherein in each case 0≤x≤1 and 0≤y≤1 applies.

In particular, the semiconductor body can have or be a semiconductor layer sequence, especially preferably an epitaxially grown semiconductor layer sequence. In particular, the semiconductor body may be deposited on a substrate. For this purpose, the semiconductor layer sequence can be grown on a growth substrate by means of an epitaxy process, for example metal-organic vapor phase epitaxy (MOVPE) or molecular beam epitaxy (MBE), and provided with electrical contacts. By separating the growth substrate with the grown semiconductor layer sequence, a plurality of light-emitting semiconductor chips can be produced. Further, the semiconductor body can be transferred to a carrier substrate before singulation, and the growth substrate can be thinned or completely removed. The substrate may comprise a semiconductor material, such as a compound semiconductor material system mentioned above. In particular, the substrate may comprise or be made of sapphire, GaAs, GaP, GaN, InP, SiC, Si, and/or Ge.

The semiconductor body and in particular the at least one emitter unit can have as active region, for example, a conventional pn junction, a double heterostructure, a single quantum well structure (SQW structure) or a multiple quantum well structure (MQW structure). Furthermore, cascades of type-II transitions (ICL: “interband cascade laser”) or transitions only in the conduction band (QCL: “quantum cascade laser”) are also possible, for example. In addition to the active region, the semiconductor body can comprise further functional layers and functional regions, such as p- or n-doped charge carrier transport layers, i.e. electron or hole transport layers, undoped or p- or n-doped confinement, cladding or waveguide layers, barrier layers, planarization layers, buffer layers, protective layers and/or electrical contact points such as electrode layers, as well as combinations thereof. Furthermore, additional layers, such as buffer layers, barrier layers and/or protective layers can also be arranged perpendicular to the growth direction of the semiconductor body, for example around the semiconductor body, i.e. for example on the side surfaces of the semiconductor body.

For example, the active region of each of the emitter units may be formed as a laser medium in which, in operation, a population inversion is generated in conjunction with a suitable resonator. Due to the population inversion, the light in the active region is generated by stimulated emission resulting in the generation of laser light. Due to the generation of light by stimulated emission, the laser light usually has a very high coherence length, a very narrow emission spectrum, and/or a high degree of polarization, unlike light generated by spontaneous emission. The laser light generated in the active region forms one or more standing waves within the respective resonator corresponding to a respective length of the resonator. For this purpose, the length of the respective resonator can generally be an integer multiple of half the wavelength of the light generated in the active region during operation.

According to a further embodiment, the resonator of each of the emitter units has an outcoupling side and a rear side. In particular, the outcoupling side and the rear side may be formed by opposing side surfaces of the semiconductor body. Via the outcoupling side, an emitter unit can emit light during operation. For this purpose, the outcoupling side can be non-reflective or preferably partially reflective. The rear side can be embodied in such a way that no light or at least less light is emitted than via the outcoupling side. Thus, for example, the rear side can be fully mirrored or also partially mirrored. Furthermore, it is also possible for the rear side to be non-reflective.

“Anti-reflective” can mean here and hereinafter that there is as little reflection as possible, which may correspond to a reflection coefficient of less than or equal to 5% or of less than or equal to 2% or preferably of less than or equal to 1%. “Fully mirrored” can mean here and hereinafter that there is as little transmission as possible, which may correspond to a reflection coefficient of greater than or equal to 95% or of greater than or equal to 98% or preferably of greater than or equal to 99%. “Partially mirrored” can mean here and hereinafter that there is a reflection coefficient that is between the aforementioned values for anti-reflective and fully mirrored. Terms such as “non-reflective”, “partially reflective”, “fully reflective”, “reflective”, etc., refer beforehand and hereinafter, unless otherwise specified, to the light generated in the active region of the emitter units.

According to a further embodiment, the emission directions of the emitter units point in the same direction. The emitter units of the light-emitting semiconductor chip thus emit light in the same direction during operation. Furthermore, the emitter units can be formed next to each other in the semiconductor body, particularly preferably perpendicular to the radiation emission direction, so that the outcoupling side and the rear side of the emitter units can preferably be formed by the same side surfaces of the semiconductor body in each case.

According to a further embodiment, each emitter unit has the active region fully penetrated by at least one recess in the semiconductor body. This can mean that each emitter unit has at least one recess that completely penetrates the active region. In other words, the active region of each emitter unit is interrupted by a recess. The at least one recess is formed, for example, as a gap or slit and particularly preferably has a main extension direction that is non-parallel and preferably perpendicular to the radiation emission direction.

According to a further embodiment, each of the emitter units has a recess that is separate from the recesses of the other emitter units. In other words, the semiconductor body has separate recesses, with the active region of each emitter unit penetrated by a dedicated recess. Alternatively, the semiconductor body may have a recess extending through the active regions of two or more, and preferably all, of the emitter units. In the latter case, all active regions of the light-emitting semiconductor chip can thus be penetrated by a single recess.

The embodiments and features described below for the at least one recess refer both to the case where each of the emitter units has a respective recess dedicated to it and to the case where a common recess extends through the active regions of more than one emitter unit. Thus, the at least one recess referred to in the following may refer to a respective recess dedicated to each emitter unit or to a common recess.

According to a further embodiment, for each emitter unit the at least one recess has a first side surface and a second side surface opposite the first side surface. The first and second side surfaces are arranged in particular one after the other along the radiation emission direction and are thus those side surfaces of the at least one recess by which the at least one recess is bounded along the radiation emission direction. For example, the recess has a rectangular base surface. For example, the first side surface and the second side surface run parallel to the main extension direction. Furthermore, the recess may have, for example, a wedge-shaped and/or an at least partially rounded base surface. For this purpose, at least one side surface can run at least partially obliquely to the main extension direction and/or can run at least partially curved.

For each emitter unit, the at least one recess in the region of the active region has a recess width that is measured along the radiation emission direction. In particular, the recess width can thus be measured in a direction that is perpendicular or substantially perpendicular to the main extension direction of the recess. In the case of a recess having a non-rectangular base surface, the recess width may preferably be an average width averaged over the region in which light is generated in the respective emitter unit during operation. Preferably, for each emitter unit, the recess width is greater than or equal to 100 nm or greater than or equal to 300 nm or greater than or equal to 500 nm and less than or equal to 20 μm or less than or equal to 10 μm or less than or equal to 5 μm.

According to a further embodiment, the recess widths of the emitter units are at least partially different. In other words, at least one first emitter unit has a first recess width and at least one second emitter unit has a second recess width, wherein the first and second recess widths are different. In the case of more than two emitter units, the respective recess widths are preferably in pairs different and thus are all different. Furthermore, it is also possible that, for example, groups of two, three or more emitter units, for example pairs or triples of emitter units, have the same recess width, but the recess widths differ from group to group. The groups can have the same or different numbers of emitter units. Thus, for example, it may also be possible for the plurality of emitter units to have a group of multiple emitter units each having the same recess width, while the remaining emitter units of the plurality of emitter units have recess widths that differ from each other. By having a plurality of emitter units in a group, the respective emission spectrum can be amplified in the overall spectrum, for example, which can improve color reproduction. In the case of separately formed recesses for the emitter units, each of the recesses can particularly preferably be formed with a recess width that differs from the recess widths of the other emitter units. In the case of a recess extending through the active regions of several or preferably all emitter units, the recess width of the at least one recess may increase continuously or stepwise from emitter unit to emitter unit.

The recess widths of the emitter units may differ by an amount that is greater than or equal to 1 nm or greater than or equal to 2 nm or greater than or equal to 5 nm or greater than or equal to 10 nm. Further, the recess widths of the emitter units may differ an amount that is less than or equal to 2 μm or less than or equal to 1 μm or less than or equal to 500 nm or less than or equal to 200 nm or less than or equal to 100 nm or less than or equal to 90 nm or less than or equal to 75 nm or less than or equal to 60 nm or less than or equal to 50 nm. Further, the recess widths of the emitter units may differ by an amount that is greater than or equal to 1% or greater than or equal to 2% or greater than or equal to 5% or greater than or equal to 10% and less than or equal to 25% or less than or equal to 20% or greater than or equal to 15% or less than or equal to 10% of the characteristic wavelength of the light generated in the emitter units in operation.

According to a further embodiment, the light-emitting semiconductor chip comprises at least three emitter units, wherein the recess widths of the emitter units differ equidistantly from each other. In other words, the light-emitting semiconductor chip may have a first emitter unit with a first recess width, a second emitter unit with a second recess width, and a third emitter unit with a third recess width. The difference between the first and second recess widths is equal to the difference between the second recess width and the third recess width in the case of an equidistant difference. In the case of a fourth emitter unit having a fourth recess width, the difference between the third and fourth recess widths is equal to the two aforementioned differences. If more than four emitter units are present, the foregoing preferably applies analogously.

In the light-emitting semiconductor chip described here, at least one recess, for example in the form of a slit, is made for each emitter unit. The at least one recess can be defined, for example, by a photo technique and produced by plasma etching and/or wet chemical etching. In particular, all recesses of the semiconductor body can be fabricated together in the same process steps. Due to the at least one recess in the active region of each emitter unit, a wavelength-dependent reflectivity can be achieved, wherein the reflection spectrum is influenced by the recess width, i.e. the slit width.

In a light-emitting semiconductor chip with multiple emitter units, typically all emitter units would have the same wavelength with respect to the light generated in each case, with the same operating parameters. However, if they are to have emission wavelengths that differ from each other by a certain amount, this can be achieved by varying the recess width from emitter unit to emitter unit as described previously. For example, the recess width can increase from a first emitter unit to a last emitter unit. This shifts the reflection maximum so that the different emitter units are forced to different wavelengths. The operating parameters, i.e. in the case of a laser light source the laser parameters such as threshold, slope and voltage, essentially do not change as a result. For all of the following embodiments, the spectral adaptation of the emitter units by changing the recess width is technically easy to realize, but the operating parameters are at least essentially not affected.

For each emitter unit, the at least one recess may preferably be provided and arranged to electrically and/or optically isolate different segments of the emitter units of the semiconductor body from each other. The segments of the emitter units may have the same or different functionalities.

According to a further embodiment, for each emitter unit, the at least one recess has at least one coating that specifies a reflectivity of the recess for the light generated in the active region. In other words, a desired reflectivity of the at least one recess for the light generated in the active region of the respective emitter unit can be set by means of the coating, which can be formed, for example, in the form of one or more layers on at least one or more side surfaces of the at least one recess and/or as a filling. Alternatively, the at least one recess for one or more or all emitter units can also be free of a coating. The reflectivity of the recess can be adjusted for each emitter unit in particular such that the at least one recess is non-reflective, partially reflective or fully reflective as described above. Particularly preferably, the emitter units have the same coating. Particularly preferably, in the case of a coating in the at least one recess, the reflectivity of the at least one recess with the coating is less than or equal to 99.9% and greater than or equal to 80%.

According to a further embodiment, for each emitter unit, the first side surface has a first coating that specifies a reflectivity for the light generated in the active region. Alternatively or additionally, the second side surface has a second coating that specifies a reflectivity for the light generated in the active region. Particularly preferably, the emitter units have an identical coating, i.e. an identical first coating and/or an identical second coating.

According to a further embodiment, the first coating and the second coating are the same. Alternatively, the first and second coatings can also be formed differently from one another.

All features and embodiments described in connection with the first coating can also be embodied in the second coating and vice versa. In particular, the features and embodiments described above and below for the coating can be the same for all emitter units, so that the emitter units preferably differ only in the recess width.

As mentioned before, the first coating and/or the second coating advantageously set the reflectivity for the light of the active region of each of the emitter units to a predetermined value. For example, the first coating provides a different reflectivity for the light generated in the active region than the second coating. For example, the first coating has a low reflectivity while the second coating has a high reflectivity. Likewise, it is possible that the first coating is highly reflective while the second coating is low reflective. Thus, an electrical and/or optical isolation of different segments of the emitter units of the semiconductor body from each other can be achieved.

The term “highly reflective” means in particular that an element so designated reflects at least 20% or at least 40% or at least 50% or at least 80% of the light generated in the active region. The term “low reflective” means in particular that an element so designated reflects at most 20% or at most 5% or at most 2% and at least 0.1% or at least 1% of the light generated in the active region.

According to a further embodiment, the first coating is formed as a first layer sequence with a plurality of individual layers. For example, the individual layers are formed from two different materials and are arranged alternately. More than two different materials may also be used for the individual layers. Alternatively or additionally, the second coating may be formed as a second layer sequence having a plurality of individual layers. For example, the individual layers may have a thickness of λ/2 or λ/4 or multiples thereof, referring to the light generated in the active region, wherein λ can denote the characteristic wavelength of the light generated in the active region.

Preferably, the first coating and/or the second coating has a dielectric material or is formed from a dielectric material. For example, the individual layers have a dielectric material or are formed from a dielectric material. Suitable dielectric materials are, for example, compounds from the group of oxides or nitrides or oxynitrides of Al, Ce, Ga, Hf, In, Mg, Nb, Rh, Sb, Si, Sn, Ta, Ti, Zn, Zr.

For example, the first layer sequence and the second layer sequence are formed from individual layers of the same materials and with the same sequence, wherein a thickness of the first layer sequence in the region of the first side surface and a thickness of the second layer sequence in the region of the second side surface are formed identically or, particularly preferably, differently from one another.

According to a further embodiment, the thickness of the first coating in the region of the first side surface to a thickness of the second coating in the region of the second side surface has a ratio between 1:1 and 1:20 inclusive, preferably between 1:1 and 1:10 inclusive, more preferably between 1:1.5 and 1:4.5 inclusive.

According to a further embodiment, the thickness of the second coating in the region of the second side surface to a thickness of the first coating in the region of the first side surface has a ratio between 1:1 and 1:20 inclusive, preferably between 1:1 and 1:10 inclusive, particularly preferably between 1:1.5 and 1:4.5 inclusive.

According to a further embodiment, the second layer sequence is identical to the first layer sequence except for an additional symmetry-breaking layer. The symmetry-breaking layer can be a single layer or a layer sequence. Alternatively, it is also possible that the first layer sequence is formed identically to the second layer sequence except for an additional symmetry-breaking layer. In particular, a different formation of the first layer sequence and the second layer sequence, for example by including a symmetry-breaking layer and in particular a symmetry-breaking layer sequence in one of the two layer sequences, leads to different optical properties of the first coating and the second coating.

For example, the first coating and the second coating, for each emitter unit, completely fill the at least one recess. Further, it is also possible that between the first coating and the second coating, a region of the recess remains free of the first coating and the second coating. The region of the recess that remains free of the first coating and the second coating may be filled with a further material, which may also be referred to as a filling, and which is preferably formed with or from a dielectric such as silicon dioxide, titanium dioxide, silicon nitride. Thus, loss of light due to large refractive index differences between the semiconductor material and the dielectric can at least be reduced in the light coupling between the regions separated by the at least one recess.

According to a further embodiment, the light-emitting semiconductor chip comprises a semiconductor body having a plurality of emitter units each formed with a first segment and a second segment, the first segment being electrically and/or optically isolated from the second segment by the at least one recess. In particular, the emitter units may be formed identically with respect to the segments.

The first segment and the second segment have different functionalities, for example. Furthermore, it is also possible that several segments of an emitter unit have the same functionality. The first segment and the second segment are particularly preferably arranged along the radiation emission direction of the respective emitter unit. For example, a first contact point is applied to the first segment and a second contact point is applied to the second segment. The two contact points are set up to contact the two segments electrically independently of one another.

Each of the emitter units can also have more than two segments. In the following, only one emitter unit with two segments will be discussed in detail for the sake of simplicity. All embodiments and features disclosed in connection with the first and the second segment can also be embodied for further segments and in particular for all emitter units. Depending on the functionality of the segments, at least one recess can be arranged in the region of the rear side and/or at least one recess can be arranged in the region of the outcoupling side in each emitter unit.

According to a further embodiment, the first segment comprises the light generating part and the second segment comprises a modulation element embodied to modulate an intensity of the light generated in the active region. For example, light is generated in the first segment, preferably laser light, which enters the modulation element through the at least one recess. The modulation element can be made from transmissive to absorbent of the light via the second contact point by a variation in the current, in particular by an electrical control including reverse voltage and forward current. If the modulation element is embodied to be absorbent for the light from the light-generating part, the modulation element is embodied as an absorber element.

According to a further embodiment, the first segment and the second segment are electrically separated from each other and the second segment comprises an electrical switching element embodied to turn the emitter unit on and off.

According to a further embodiment, at least one or more or all of the emitter units comprise a segment having one or more of the following: photodiode, passive waveguide, active waveguide, beam splitter, beam combiner, lens, wavelength selective element, phase shift elements, frequency doubler, taper, amplifier, converter, transistor.

As an alternative to being embodied as a laser light source, the emitter units can also be embodied, for example, as a super luminescent diode, in which amplification of the light generated in the active region takes place within a resonator, but full laser operation is not achieved.

According to a further embodiment, for example, a semiconductor body is provided by growth comprising an active layer having a plurality of active regions embodied and intended to generate light in operation and arranged in a resonator. Each of the active regions is associated with an emitter unit, such that the semiconductor body comprises a plurality of monolithically integrated emitter units, each having an active region.

Furthermore, in each of the emitter units, at least one recess is created in the semiconductor body, wherein, for each of the emitter units, the at least one recess completely penetrates the respective active region. For each of the emitter units, the at least one recess has a first side surface and a second side surface, the first side surface being disposed opposite the second side surface. For example, for each emitter unit, the at least one recess is produced by etching. As described above, for each of the emitter units, the at least one recess has a recess width along the radiation emission direction, which may particularly preferably correspond to a distance between the first and second side surfaces along the radiation emission direction. The emitter units are manufactured such that the recess widths differ. Particularly preferably, this can be produced in a common process step both in the case where each emitter unit has a recess assigned specifically to it and in the case where a recess extends through the active regions of several emitter units.

According to a further embodiment, a coating is applied for each emitter unit, particularly preferably in a common process step, such as a first coating on the first side surface and/or a second coating on the second side surface.

For example, it may also be the case that, for each emitter unit, the second side surface of the at least one recess is provided with a protective layer. In a next step, the first side surface of the at least one recess can be provided with the first coating for each emitter unit and the protective layer can be removed again so that the semiconductor body is freely accessible in the region of the second side surface in each case. For example, a photoresist layer can be used as the protective layer.

For example, the first coating and/or the second coating can be deposited by means of evaporation, sputtering, atomic layer deposition (“ALD”) or chemical vapor deposition (“CVD”).

During evaporation and sputtering, the surface to be coated is provided in a volume. In the volume, at least one starting material in the gas phase is furthermore provided. The starting material condenses directly on the surface, forming a coating on the surface. In vapor deposition, the starting material is vaporized by applying temperature, while in sputtering, the starting material is vaporized by ion bombardment. Vapor deposition and sputtering are generally directional deposition processes in which more material is deposited along one preferred direction than along the other directions.

In the CVD process, the surface to be coated is also provided in a volume. Furthermore, at least one starting material is provided in the volume, from which a solid coating is deposited by a chemical reaction on the surface to be coated. Generally, at least a second starting material is provided in the volume, with which the first starting material chemically reacts to form the solid coating on the surface. Thus, the CVD process is characterized by at least one chemical reaction at the surface to be coated to form the CVD coating. More than two starting materials can also be used in the chemical vapor deposition process.

Atomic layer deposition refers to a process in which the first gaseous starting material is added to the volume in which the surface to be coated is provided, so that the first gaseous starting material adsorbs on the surface. After a preferably complete or nearly complete coverage of the surface with the first starting material, the part of the first starting material that is still present in gaseous form or not adsorbed on the surface is generally removed from the volume again and the second starting material is supplied. The second starting material is intended to react chemically with the first starting compound adsorbed on the surface to form a solid coating.

The CVD process and the ALD process are usually non-directional or also so-called isotropic deposition processes, in which the material is deposited uniformly along all directions.

Furthermore, it may be that the first coating is provided with a further protective layer at least in the region of the first side surface. This step usually takes place after the first coating has been applied to the first side surface. The second side surface particularly preferably remains free of the protective layer.

Furthermore, the second side surface can be provided with the second coating and the further protective layer can be removed again so that the first coating is freely accessible in the area of the first side surface. This is preferably done after the second coating has been applied. With the aid of the two protective layers, it is advantageous to be able to produce two coatings which are different from one another.

As described above, the first coating and the second coating may be applied to the first side surface and the second side surface in sequential steps in time.

According to a further embodiment, the first coating and the second coating are applied simultaneously to the first side surface and the second side surface. In this embodiment of the process, the first coating is preferably formed as a first layer sequence of a plurality of individual layers and the second coating is formed as a second layer sequence of a plurality of second individual layers. Particularly preferably, in this embodiment of the process, the first layer sequence and the second layer sequence have individual layers of the same materials and the same sequence. Particularly preferably, however, the first layer sequence and the second layer sequence differ in their thicknesses. Preferably, a thickness of the first layer sequence in the region of the first side surface to a thickness of the second layer sequence in the region of the second side surface has a ratio between 1:1 inclusive and 1:20 inclusive, preferably between 1:1 inclusive and 1:10 inclusive, particularly preferably between 1:1.5 inclusive and 1:4.5 inclusive.

To produce such coatings, preferably a deposition process is used in which a preferred direction for depositing the first coating and the second coating includes a predetermined angle with a main extension plane of the semiconductor body. Preferably, the angle is not equal to 90°. In this way, a first coating and a second coating can be obtained whose thicknesses, on the first side surface and the second side surface, are different from one another but have the same materials and sequences of individual layers. In other words, a directional deposition process, such as thermal evaporation or sputtering, is particularly preferred here.

According to a further embodiment, prior to applying the first coating and the second coating, a shading element is applied to a region of a major surface of the semiconductor body that is directly adjacent to the first side surface of the at least one recess for each emitter unit, such that the thickness of the first coating in the region of the first side surface is different from the thickness of the second coating in the region of the second side surface. Thus, even with the aid of a shading element, a first coating and a second coating can be applied simultaneously to the side surfaces, which have different thicknesses at least in the region of the first side surface and the second side surface.

According to a further embodiment, the first coating is formed as a first layer sequence with a plurality of individual layers. According to a further embodiment of the method, the second coating is formed as a second layer sequence with a plurality of individual layers.

The at least one recess can be arranged, for each emitter unit, in the region of the rear side or in the region of the outcoupling side. In the region of the rear side can mean in particular that the at least one recess is arranged, along the radiation emission direction, closer to the rear side than to the outcoupling side. In the region of the outcoupling side can mean in particular that the at least one recess is arranged, along the radiation emission direction, closer to the outcoupling side than to the rear side.

In a preferred embodiment, the at least one recess in each emitter unit is preferably formed in the region of the rear side of the resonator so that the rear side reflectivity can be modulated. By means of a purposeful coating, which can advantageously already be applied in the wafer composite, the appropriate reflectivity and modulation is generated depending on the recess width. Due to the fact that the at least one recess is formed in the rear side region, the light coupled out on the outcoupling side does not have to propagate through the at least one recess, resulting in a better beam quality.

Alternatively or additionally, at least one recess can also be formed in the area of the outcoupling side for each emitter unit, wherein a dependence on the recess width also results. This can be particularly advantageous for multi-sectional devices, while the design on the rear side is also possible for “simple” laser resonators.

Furthermore, it is also possible to form at least one recess in the region of the rear side and at least one recess in the region of the outcoupling side for each emitter unit in order to enhance the modulation effect or to achieve even narrower reflection maxima. Since the maxima of the reflection spectrum have a certain spectral width, a significantly narrower wavelength window in which the emitter units must emit can be achieved by two spectra slightly shifted against each other in the region of the rear side and in the region of the outcoupling side. Advantageously, the operation does not depend on the absolute recess width in the emitter units, but only on the relative recess width differences between the emitter units, since the modulation repeats periodically with the recess width. As a result, production fluctuations in the recess width are not critical and this solution is technically very easy to implement.

In the light-emitting semiconductor chip described herein, it may thus be possible to achieve a variation of the wavelength across the individual emitter units of a light-emitting semiconductor chip with a defined shift, which leaves the operating parameters approximately the same. Furthermore, such a solution may be applicable to special devices such as multi-segment lasers, since the formation of multiple segments may extend the functionality of the emitter units with respect to optimal usability in optical devices. For example, a light-emitting semiconductor chip with emitter units can each be formed with an amplifier section and a modulator section in order to be able to continuously control the light output even for low output powers, which can be very advantageous for high contrast imaging.

The light-emitting semiconductor chip described herein may be used in any of the following applications, for example: augmented reality, virtual reality, pico-projection, LIDAR (“light detection and ranging”), message transmission.

With the light-emitting semiconductor chip described here, it is possible in particular to realize different wavelengths with adjacent emitter units in a simple manner, which would otherwise be difficult to achieve. The simplicity of the process allows low-cost production. Due to the different wavelengths, a significantly improved image quality can be achieved, for example in AR/VR applications. The described process is insensitive to process variations, so high and stable manufacturing yields may be achievable. In-situ control is not necessary due to the stability against process fluctuations, which can save costs.

### BRIEF DESCRIPTION OF THE DRAWINGS

Further advantages, advantageous embodiments and further developments are revealed by the embodiments described below in connection with the figures.

FIGS. 1A to 1E show schematic illustrations of a light-emitting semiconductor chip and various stages of a method for manufacturing the light-emitting semiconductor chip, and an exemplary emission spectrum according to an embodiment;

FIGS. 2A and 2B show schematic illustrations of parts of light-emitting semiconductor chips according to further embodiments;

FIGS. 3A to 3D show simulations of the reflectivity R as a function of the wavelength λ for a coating according to an embodiment;

FIGS. 4A and 4B show simulations of the reflectivity R and mirror losses L as a function of the wavelength λ for a coating according to an embodiment;

FIGS. 5A and 5B show a schematic illustration of a part of a light-emitting semiconductor chip and a simulation of the reflectivity R as a function of the wavelength λ for a coating according to an embodiment;

FIGS. 6A and 6B show schematic illustrations of a light-emitting semiconductor chip according to a further embodiment;

FIGS. 7A and 7B show schematic illustrations of a light-emitting semiconductor chip according to a further embodiment;

FIGS. 8A and 8B show schematic illustrations of a light-emitting semiconductor chip according to a further embodiment;

FIGS. 9A and 9B show simulations of the reflectivity R as a function of the wavelength λ for coatings according to further embodiments;

FIGS. 10A to 10C show a schematic illustration of a part of a light-emitting semiconductor chip and simulations of the reflectivity R as a function of the wavelength λ for coatings according to further embodiments;

FIGS. 11A to 11C show simulations of the reflectivity R as a function of the wavelength λ for coatings according to further embodiments;

FIGS. 12A to 12E show simulations of the reflectivity R and the gain G as a function of the wavelength λ and of spectral parameters as a function of the recess width A for a coating according to a further embodiment; and

FIGS. 13A to 19C show schematic illustrations of light-emitting semiconductor chips and parts thereof according to further embodiments.

### DETAILED DESCRIPTION OF ILLUSTRATIVE EMBODIMENTS

In the embodiments and figures, identical, similar or identically acting elements are provided in each case with the same reference numerals. The elements illustrated and their size ratios to one another should not be regarded as being to scale, but rather individual elements, such as for example layers, components, devices and regions, may have been made exaggeratedly large to illustrate them better and/or to aid comprehension.

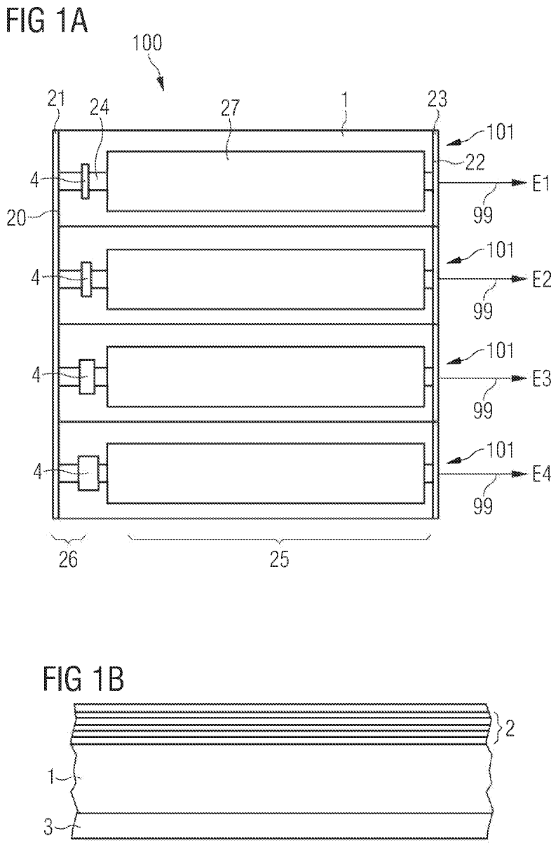

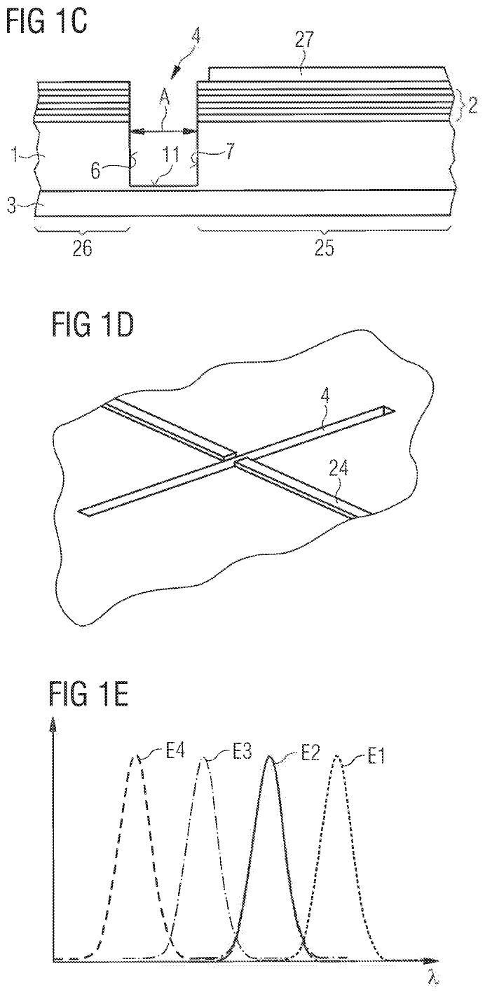

In connection with FIGS. 1A to 1E, an embodiment of a light-emitting semiconductor chip 100 and method steps for manufacturing the same are shown. FIG. 1A shows a top view of the light-emitting semiconductor chip 100, FIGS. 1B to 1D show process steps in sectional views, and FIG. 1E shows an exemplary emission spectrum of the light-emitting semiconductor chip 100. The following description refers equally to FIGS. 1A to 1E.

The light-emitting semiconductor chip 100, which is embodied in particular as a multi-emitter laser light source, has a semiconductor body 1 which has a plurality of emitter units 101. Purely by way of example, four emitter units 101 are indicated in FIG. 1A, each of which has an active region 2 in which, during operation, light is generated which is emitted along the indicated emission directions 99 from the emitter units 101 via an outcoupling side 22. The light-emitting semiconductor chip 100 may also have more or fewer emitter units 101.

The semiconductor body 1 is deposited as a semiconductor layer sequence on a substrate 3. For example, the semiconductor body 1 may be grown on the substrate 3 as described in the general part and may have a material described in the general part. The semiconductor layer sequence and in particular the active region 2, which may have for example one or as indicated in the figures several layers, may be formed as described in the general part. For the sake of clarity, no further individual layers of the semiconductor body 1 are indicated in the figures apart from the active region 2.

The active region 2 of each of the at least one emitter unit 10 is arranged in a resonator. In particular, the resonator is configured to amplify the light generated in the active region 2. For example, the resonator as well as an exemplary ridge waveguide structure 24, which may also be referred to as a ridge, may define the radiation emission direction 99 along which light is emitted by an emitter unit 101 during operation. In the illustrated embodiment, the resonator is bounded by a first layer 21 on a rear side and a second layer 23 on an outcoupling side 22, the rear surface 20 and the outcoupling side 22 being side surfaces of the semiconductor body 1. For example, the first layer 21 may be a layer or sequence of layers that partially or fully mirrors the rear side 20, while the second layer 23 may be a layer or sequence of layers that form(s) a partial mirroring on the outcoupling side 22.

A recess 4 is created in the semiconductor body 1 for each emitter unit 101, which completely penetrates the respective active region 2. In the embodiment shown, each emitter unit 101 has a dedicated recess 4 that is separate from the recesses 4 of the respective other emitter units 101. The recesses 4 may penetrate the semiconductor body 1 completely or, as indicated in the figures, partially. In particular, the recesses 4 may extend into a semiconductor layer of the semiconductor body 1 below the active region 2, for example, into a waveguide layer, a cladding layer or a buffer layer.

The recesses 4 each have a first side surface 6 and a second side surface 7 opposite the first side surface 6, and a bottom surface 11. The recesses 4 are created, for example, by etching such as plasma etching and/or wet chemical etching in a common-mask based and photo-based process. For this purpose, one or more etch stop layers may be present in the semiconductor body 1 to stop an etching process of the recesses 4 and thus define the bottom surface 11. Thus, a depth of the recesses 4 can be defined. The cross-sectional view of one of the recesses 4 with vertical side walls 6, 7 indicated in a partial view of a sectional view through the light-emitting semiconductor chip 101 in FIG. 1C is purely exemplary. Depending on the etching process, the shape of the sidewalls may differ from the shape shown.

The active region 2 of each emitter unit 101 is thus disconnected by a recess 4. The respective recess 4 is formed, for example, as a gap or slit and particularly preferably has a main extension direction, which is non-parallel and preferably perpendicular to the radiation emission direction 99, as indicated in a three-dimensional section in FIG. 1D. The first and second side surfaces 6, 7 are in particular arranged one after the other along the radiation emission direction 99 and are thus, for each emitter unit 101, those side surfaces of the respective recess 4 by which the recess 4 is bounded along the radiation emission direction 99. For example, the recesses 4 have a rectangular base surface as shown. Here, the first side surface 6 and the second side surface 7 run parallel to the main extension direction of the respective recess 4. Furthermore, as shown further below, the recesses 4 can have, for example, a wedge-shaped and/or an at least partially rounded base surface. For this purpose, at least one of the first and second side surfaces 6, 7 may be at least partially oblique to the main extension direction and/or at least partially curved.

For each emitter unit 101, the respective recess 4 in the region of the active region 2 has a recess width A, which is measured along the radiation emission direction 99. In particular, the recess width A can thus be measured in a direction that is perpendicular or substantially perpendicular to the main extension direction of the recess 4. Preferably, for each emitter unit 101, the recess width A is greater than or equal to 100 nm or greater than or equal to 300 nm or greater than or equal to 500 nm and less than or equal to 20 μm or less than or equal to 10 μm or less than or equal to 5 μm.

As indicated in FIG. 1A, the recess widths A of the emitter units 101 are different. In other words, each emitter unit has a recess 4 having a recess width A, the recess widths A being different from each other in pairs.

The recess widths A of at least two or more or all of the emitter units 101 may each differ in pairs by an amount that is greater than or equal to 1 nm or greater than or equal to 2 nm or greater than or equal to 5 nm or greater than or equal to 10 nm and that is less than or equal to 2 μm or less than or equal to 1 μm or less than or equal to 500 nm or less than or equal to 200 nm or less than or equal to 100 nm or less than or equal to 90 nm or less than or equal to 75 nm or less than or equal to 60 nm or less than or equal to 50 nm. Further, the recess widths A of the emitter units 101 may differ by an amount that is greater than or equal to 1% or greater than or equal to 2% or greater than or equal to 5% or greater than or equal to 10% and less than or equal to 25% or less than or equal to 20% or greater than or equal to 15% or less than or equal to 10% of the characteristic wavelength of the light generated in the emitter units 101 during operation.

In a particularly preferred embodiment, the recess widths A of the emitter units 101 are equidistantly different from each other. In the embodiment shown, this means that the difference between the recess widths of the two uppermost emitter units 101 shown in FIG. 1A is equal to the difference between the recess widths of the two middle emitter units 101 shown in FIG. 1A, which in turn is equal to the difference between the recess widths of the two lowermost emitter units 101 shown in FIG. 1A.

By means of the respective recess 4 in the active region 2 of each emitter unit 101, a wavelength-dependent reflectivity can be achieved, wherein the reflection spectrum is influenced by the respective recess width A. By varying the recess widths A, the emitter units can thereby emit emission spectra E1, E2, E3 and E4 with different emission wavelengths, as exemplified in FIG. 1E. For a light-emitting semiconductor chip 100 with emission spectra in the visible wavelength range, the spectral spacing of the individual emission spectra E1, E2, E3, E4 can be greater than or equal to +/−0.5 nm, preferably greater than or equal to +/−1.0 nm and particularly preferably greater than or equal to +/−3 nm, by varying the recess width A.

For application in other wavelength ranges, for example shorter wavelengths or in the infrared spectral range, such as for infrared imaging, gas sensing or other applications where shifted emission wavelengths in a multi-emitter chip are relevant, typically the relevant wavelength spacing and the total wavelength width to be covered scales with the wavelength itself.

For the present embodiment and for all the following embodiments, the spectral adaptation of the emitter units by changing the slit width is technically easy to realize and it substantially does not affect the operating parameters.

For each emitter unit 101, the respective recess 4 is preferably provided and arranged to electrically and/or optically isolate different segments 25, 26 of the emitter units 101 of the semiconductor body 1 from each other. The segments 25, 26 of the emitter units 101 may have the same or different functionalities. In FIGS. 1A and 1C, two segments 25, 26 are indicated, of which a first segment 25 is electrically contacted by means of a first electrical contact point 27, for example in the form of an electrode layer, while the other, second segment 26 remains uncontacted. Alternatively, as described further below, the segments can be contacted separately. Alternatively, the segments can be short-circuited via a common contact point.

The position of the recess 4 of each of the emitter units 101 may be located at any point along the overall resonator length, but preferably in the region and in particular close to the rear side 20, as is the case in the present embodiment, or in the region and in particular close to the outcoupling side 22, as is described further below.

By separating the cavities of the emitter units 101 into two segments or, in the case of forming multiple recesses 4 per emitter unit 101 as shown further below, into more than two segments, the segments can be formed for adjusting different properties of the light-emitting semiconductor chip 100. For example, a segment that is not electrically contacted and thus passive may be formed as a passive mode filter or for spectral broadening, for example in a super luminescent diode. An electrically separately contacted and thus active segment may be formed as a modulator or dimmer or with another functionality as described in the general part.

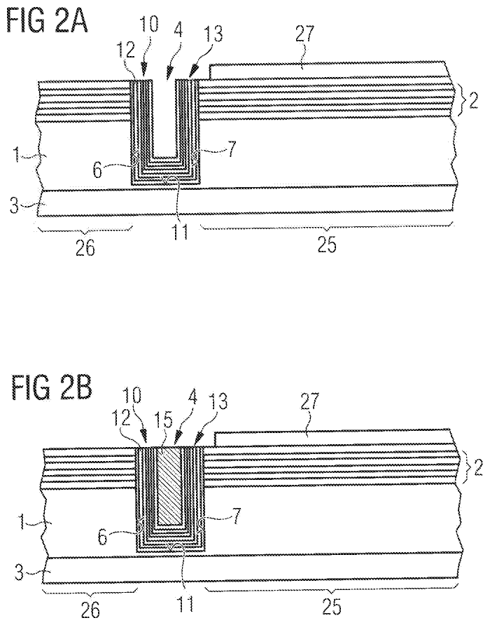

FIGS. 2A and 2B show schematic illustrations of parts of emitter units of light-emitting semiconductor chips according to further embodiments, corresponding to the views in FIGS. 1B and 1C. Compared with the previous embodiment, the emitter units according to the embodiments of FIGS. 2A and 2B have a coating in the recesses 4 that predetermines a reflectivity of the recesses 4 for the light generated in the respective active region 2. In other words, by means of the coating, which is formed in particular with a first coating 10 and a second coating 13 in the form of one or, as indicated, a plurality of layers 12, a desired reflectivity of the recesses 4 for the light generated in the active region 2 of the respective emitter unit can be set. The reflectivity of the recess 4 can be set for each emitter unit, in particular, in such a way that the respective recess 4 is non-reflective, partially reflective or fully reflective. Particularly preferably, all emitter units of the light-emitting semiconductor chip have the same coating in the respective recess 4. Particularly preferably, the reflectivity of the recesses 4 with a coating is less than or equal to 99.9% and greater than or equal to 80%.

As can be seen in FIGS. 2A and 2B, for each emitter unit, the first side surface 6 has a first coating 10 and the second side surface 7 has a second coating 13, each of which specifies a reflectivity for the light generated in the active region 2. In the embodiments of FIGS. 2A and 2B, the first coating 10 and the second coating 13 are the same. Alternatively, the first and second coatings 10, 13 may be formed differently from each other or there may be a coating on only one of the side surfaces 6, 7.

Preferably, the first coating 10 and/or the second coating 13 has a dielectric material or is formed from a dielectric material. For example, the individual layers 12 have a dielectric material or are formed from a dielectric material. Suitable dielectric materials include, for example, compounds from the group of oxides or nitrides or oxynitrides of Al, Ce, Ga, Hf, In, Mg, Nb, Rh, Sb, Si, Sn, Ta, Ti, Zn, Zr. The thicknesses of the single layers 12 can be chosen, for example, to have a thickness of λ/2 or λ/4 or multiples thereof, wherein λ denotes the characteristic wavelength of the light generated in the active region 2.

For example, for each emitter unit the first coating 10 and the second coating 13 completely fill the respective recess 4. Furthermore, it is also possible that between the first coating 10 and the second coating 13 a region of the recess 4 remains free of the first coating 10 and the second coating 13, as indicated in FIG. 2A. The region of the recess 4 which remains free of the first coating 10 and the second coating 13 may further be filled, as indicated in FIG. 2B, with a further material which may be referred to as filling 15 and which is preferably formed with or from a dielectric such as silicon dioxide, titanium dioxide, silicon nitride. Further, the filling 15 may comprise one or more materials described above in connection with the first and second coatings. Thus, in the light coupling between the segments separated by the at least one recess 4 loss of light due to large refractive index differences between the semiconductor material and the dielectric can at least be reduced. Particularly preferably, the filling 15 fills the portion of the recess 4 that is not filled by the first and second coatings 10, 13 so that the recess 4 is completely filled.

In the embodiments of FIGS. 1A to 2B, the recesses 4 are produced with different recess widths in the region of the rear side. The recesses 4 are preferably at least partially filled with layers that give the recesses 4 highly reflective properties, and have the different recess widths as described above.

The rear side preferably has a coating with the first layer described above, which has a very low reflectivity, for example, so that back reflections into the resonator can be avoided. The coated recesses 4 themselves can thus serve as a highly reflective facet. As a result of the fact that the second segments 26 to the left of the recesses 4 are not electrically contacted and are thus passive, these are, so to speak, only an “appendage” and no longer have any influence on the reflectivity as a result of the anti-reflection coating described. Alternatively, it may also be possible to use the first layer on the rear side as a rear mirror with at least partial reflectivity.

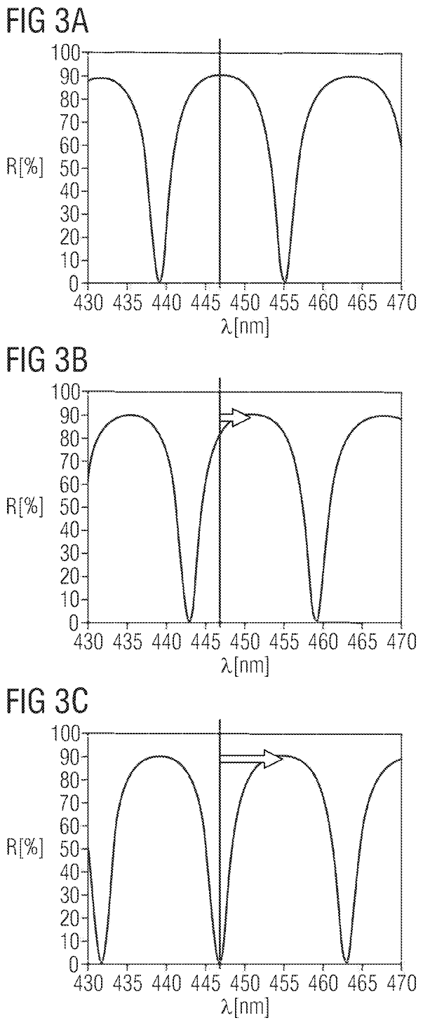

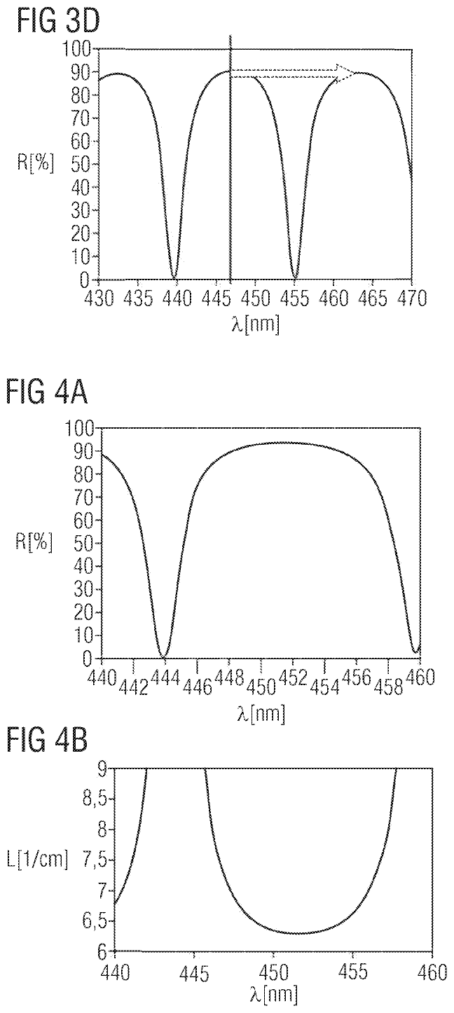

When the recess 4 is filled with pairs of layers with individual layers 12 formed at least approximately as λ/4 layers, highly reflective mirrors with strong modulation can be produced. FIGS. 3A to 3D show simulations of the reflectivity R as a function of wavelength λ for a coating 10, 13 with the composition given in Table 1.

The materials given in Table 1 and in the other tables are to be understood purely as examples to explain the underlying principles. Alternatively or additionally, other of the materials mentioned can also be used. In particular, the compositions of the materials may also deviate from a stoichiometric composition. The order of the materials from top to bottom given in Table 1 and the following tables corresponds to an order along the radiation emission direction from the first side surface to the second side surface of the recess, the side surfaces being formed by the semiconductor body, which is therefore also given at the beginning and at the end in the tables.

TABLE 1

| | | Thickness | |
|---|---|---|---|
| | Material | (nanometer) | Refractive index n |
| | semiconductor body | | 2.5 |
| first coating | SiN | 62.5 | 1.8 |
| first coating | SiO₂ | 75 | 1.5 |
| first coating | SiN | 62.5 | 1.8 |
| first coating | SiO₂ | 75 | 1.5 |
| first coating | SiN | 62.5 | 1.8 |
| first coating | SiO₂ | 75 | 1.5 |
| first coating | SiN | 62.5 | 1.8 |
| first coating | SiO₂ | 75 | 1.5 |
| first coating | SiN | 62.5 | 1.8 |
| first coating | SiO₂ | 75 | 1.5 |
| first coating | SiN | 62.5 | 1.8 |
| first coating | SiO₂ | 75 | 1.5 |
| filling | SiN | x | 1.8 |
| second coating | SiO₂ | 75 | 1.5 |
| second coating | SiN | 62.5 | 1.8 |
| second coating | SiO₂ | 75 | 1.5 |
| second coating | SiN | 62.5 | 1.8 |
| second coating | SiO₂ | 75 | 1.5 |
| second coating | SiN | 62.5 | 1.8 |
| second coating | SiO₂ | 75 | 1.5 |
| second coating | SiN | 62.5 | 1.8 |
| second coating | SiO₂ | 75 | 1.5 |
| second coating | SiN | 62.5 | 1.8 |
| second coating | SiO₂ | 75 | 1.5 |
| second coating | SiN | 62.5 | 1.8 |
| | semiconductor body | | 2.5 |

By changing the width of the recess, the width x of the filling given in the table changes while the coating remains the same, thus shifting the modulations. In FIG. 3A, for a wavelength in the range of 450 nm, the reflectivity R of the filled recess is shown as a function of the wavelength λ for x=3040 nm, which means, for example, a reflectivity maximum for an indicated wavelength of about 446 nm. For x=3070 nm (FIG. 3B) and x=3100 nm (FIG. 3C), the maximum shifts toward higher wavelengths, as indicated by the respective arrow. The shift is periodic, so in the example shown, for x=3165 nm, a maximum is again at the same position as for x=3040 nm, as shown in FIG. 3D. Due to this periodicity, the absolute recess width is not critical, since the relative changes in the recess width cause the shift.

FIGS. 4A and 4B show simulations of reflectivity R and mirror losses L as a function of wavelength λ for a coating according to a further embodiment. The mirror losses L are calculated according to the formula L=−ln((R1×R2)/(2×L)), wherein R1 is the reflectivity of the recess according to FIG. 4A, R2 is the reflectivity of the mirror formed by the second layer on the outcoupling side and L is the resonator length. For the simulation in FIG. 4B the values R2=50% and L=600 μm were assumed.

As can be easily seen in FIG. 4B, even small changes in the reflectivity of the recess result in significant changes in the specular losses L, so that the light generated in the active region is forced to the wavelength with the lowest specular losses, since a laser typically begins to lase at the wavelength with the lowest losses. Therefore, the wavelength of the light generated in the active region of an emitter unit shifts with the shift of the reflection spectrum shown in FIGS. 3A to 3D by changing the recess width. This principle is independent of whether the recesses are located in the rear side region or in the outcoupling side region.

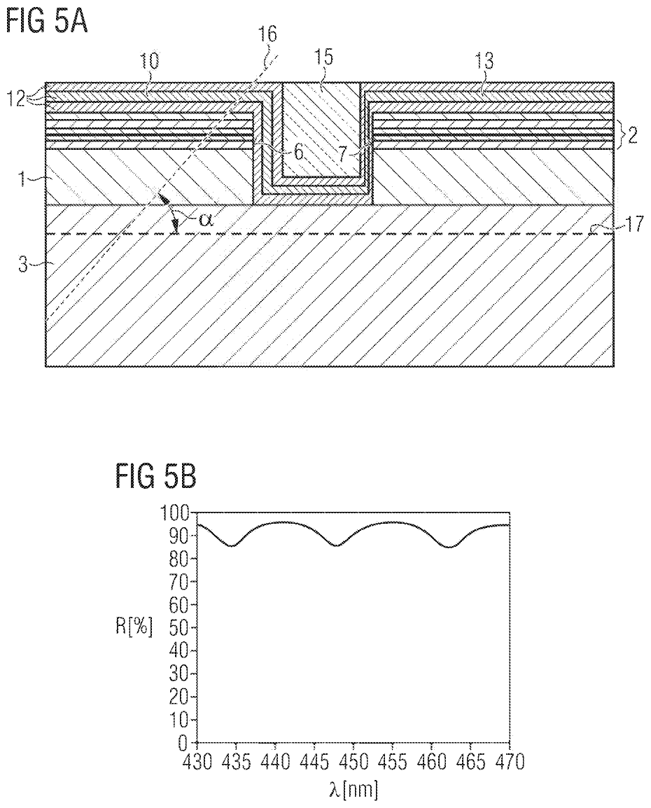

Different reflectivities, modulation depths and periodicities can be adjusted by suitable coatings. FIGS. 5A and 5B show, according to a further embodiment, a schematic illustration of a part of an emitter unit of a light-emitting semiconductor chip with different first and second coatings 10, 13 and a filling 15, as well as a simulation of the reflectivity R as a function of the wavelength λ for such a coating. Purely by way of example and for the sake of clarity, only three individual layers 12 each for the first and second coatings are shown in FIG. 5A.

Compared to the previous embodiments, the second coating 13 on the second side surface 7 is half as thick as the first coating 10 on the first side surface 6. For this purpose, for example, the first coating 10 and the second coating 13 can be deposited separately from each other and thus one after the other. Suitable process steps as described in the general part can be used for this purpose. Furthermore, the first coating 10 and the second coating 13 can also be deposited simultaneously. For this purpose, for example, a deposition method is used which has a preferred direction 16 having an angle α with a main extension plane 17 of the semiconductor body 1. Thus, a simultaneous deposition of the first coating 10 and the second coating 13 takes place, the second coating 13 having a different thickness at least on the second side surface 7 than the first coating 10 on the first side surface 6. This is achieved by a self-shading of the recess 4 during the deposition due to the preferred direction 16. For example, sputtering or vapor deposition are suitable directional deposition processes. The thickness ratio between the first and second coatings 10, 13 on the side surfaces 6, 7 can be adjusted by a suitable selection of the angle α.

The first and second coatings 10, 13 produced in this way each have a layer sequence of individual layers 12 of the same material and the same sequence. The first coating 10 and the second coating 13 differ only in their thickness on the first side surface 6 and the second side surface 7 of the recess 4. The remaining gap is filled with a filling 15 as in the embodiment of FIG. 2B.

FIG. 5B shows a simulation of the reflectivity R as a function of wavelength λ for such a coating with the first and second coatings 10, 13 and the filling 15 with the composition given in Table 2.

TABLE 2

| | | Thickness | |
|---|---|---|---|
| | Material | (nanometer) | Refractive index n |
| | semiconductor body | | 2.5 |
| first coating | SiO₂ | 73 | 1.5 |
| first coating | TiO | 47 | 2.2 |
| first coating | SiO₂ | 79 | 1.5 |
| first coating | TiO | 50 | 2.2 |
| first coating | SiO₂ | 75 | 1.5 |
| first coating | TiO | 49 | 2.2 |
| first coating | SiO₂ | 72 | 1.5 |
| first coating | TiO | 52 | 2.2 |
| first coating | SiO₂ | 78 | 1.5 |
| first coating | TiO | 44 | 2.2 |
| filling | TiO | 3000 | 2.2 |
| second coating | TiO | 22 | 2.2 |
| second coating | SiO₂ | 39 | 1.5 |
| second coating | TiO | 26 | 2.2 |
| second coating | SiO₂ | 36 | 1.5 |
| second coating | TiO | 24.5 | 2.2 |
| second coating | SiO₂ | 37.5 | 1.5 |
| second coating | TiO | 25 | 2.2 |
| second coating | SiO₂ | 39.5 | 1.5 |
| second coating | TiO | 23.5 | 2.2 |
| second coating | SiO₂ | 36.5 | 1.5 |
| | Semiconductor body | | 2.5 |

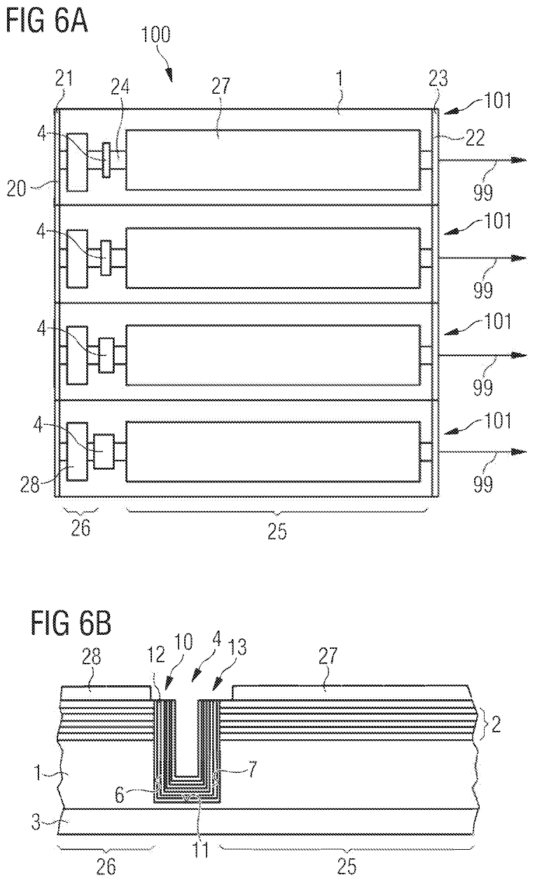

FIGS. 6A and 6B show schematic illustrations of a light-emitting semiconductor chip 100 according to a further embodiment, in which, compared to previous embodiments, in addition to the first segment 25, the second segment 26 of each emitter unit 101 is also electrically contacted by means of second electrical contact points 28, for example electrode layers. For example, the second segments 26 of the emitter units 101 may be formed and used as an integrated photodiode. For this purpose, it may be advantageous if the reflectivity of the recesses 4 is set by a suitable coating, for example, to less than or equal to 99%, preferably less than or equal to 97% and particularly preferably less than or equal to 95%. The first layer 21 on the rear side 20 is particularly preferably an anti-reflection coating in order to avoid back reflections in the direction of the first segments 25.

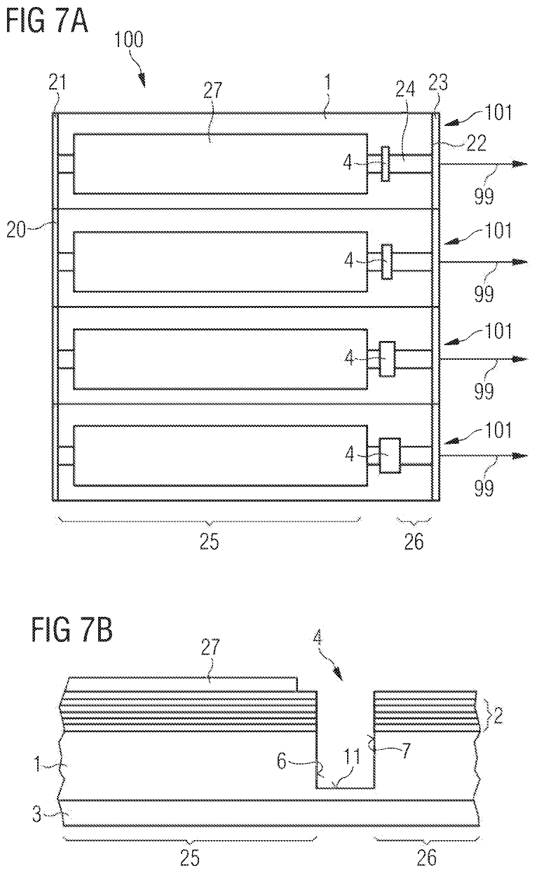

FIGS. 7A and 7B show schematic illustrations of a light-emitting semiconductor chip 100 according to a further embodiment in which, compared to the previous embodiments, the recesses 4 are arranged with different recess widths in the region of the outcoupling side 22.

The recesses 4 are unfilled as shown or can alternatively be filled, for example, with a material having a certain refractive index. The second layer 23 on the outcoupling side 22 is formed by a coating with very low reflectivity, which avoids back reflections into the semiconductor body 1.

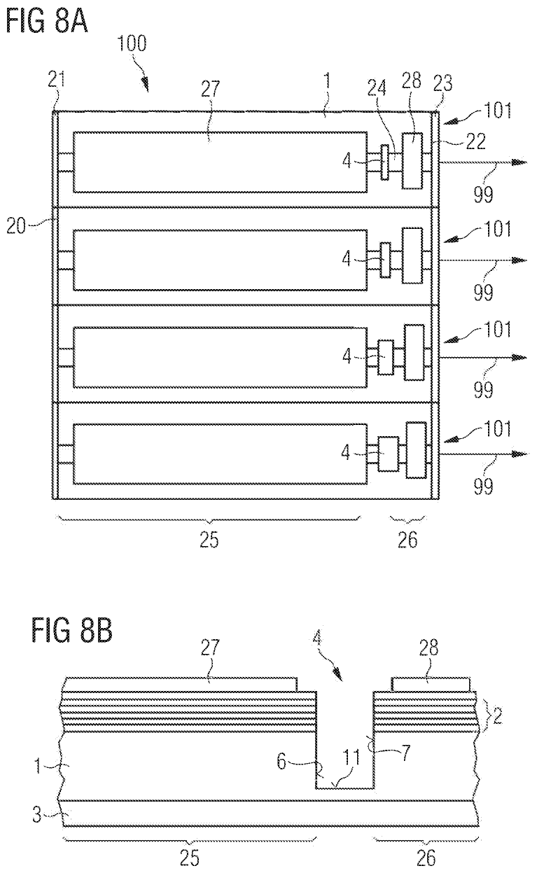

In the embodiment shown here, the second segments 26 are not electrically contacted at the outcoupling side 22 and are thus embodied as passive segments. Alternatively, however, as shown in FIGS. 8A and 8B, they can also be electrically contacted separately by means of second electrical contact points 28.

The second segments 26 do not affect the reflectivity at the outcoupling side 22 due to the non-reflective second layer 23, but rather the reflectivity is defined by the recesses 4. By effectively “relocating” the position of the outcoupling reflectivity from the facet of the semiconductor body 1 at the outcoupling side 22 of the light-emitting semiconductor chip 100 into the recesses 4, it can be advantageously achieved that the second segments 26 can be used with additional properties. For example, these can be used, possibly in combination with changes to the ridge waveguide geometry in the second segments 26, as a mode filter or for spectral broadening or as a modulator, etc.

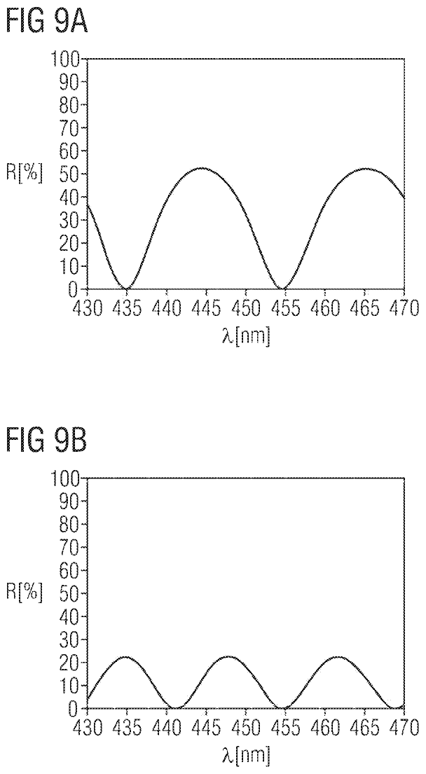

In the simplest case, the modulation can be realized via an unfilled or a material-filled recess 4 in the active regions 2 of the emitter units 101. This allows, for example, reflectivities of less than about 50% in the AlInGaN material system with air-filled recesses 4, as shown in FIG. 9A in another simulation of an air-filled recess with a recess width of 5000 nm. By filling with a material with a higher refractive index, a lower reflectivity can be set, as shown in FIG. 9B in a further simulation with such a recess filled with SiO2 with a refractive index of 1.5. Since the modulations in the case of air fillings have a relatively large spacing, a large recess width may be required to obtain the necessary smaller modulation spacing. However, since this entails a reduction in coupling efficiency, and since for some applications reflectivities are required which are greater than 50% or which cannot be set with a single filling material, multilayer coatings can be used as an alternative, such as those described below.

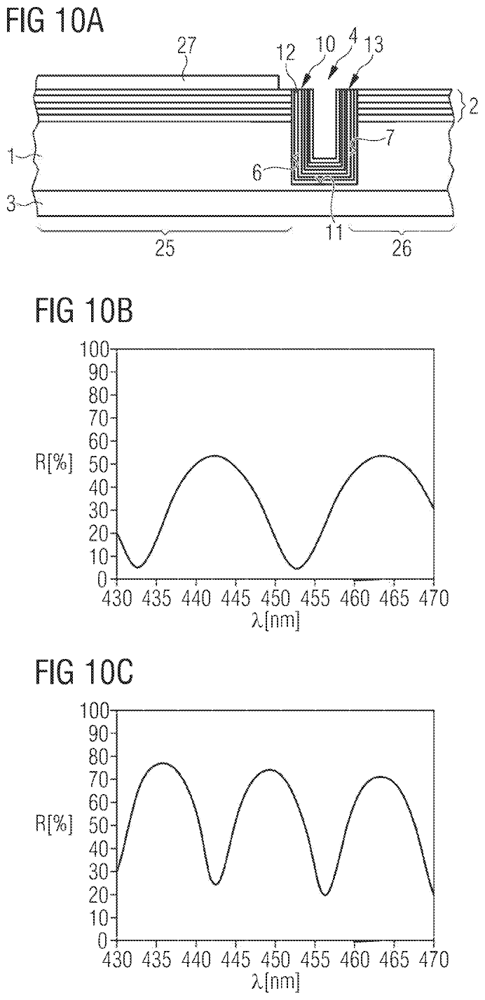

FIG. 10A shows a schematic partial illustration of an emitter unit of a light-emitting semiconductor chip according to the embodiment of FIGS. 7A and 7B, wherein, in contrast to the embodiment of FIGS. 7A and 7B, such a coating is additionally applied in the form of a first coating 10 and a second coating 13 in the recesses 4. FIGS. 10B and 10C show simulations of the reflectivity R as a function of the wavelength λ for coatings according to Tables 3 and 4.

TABLE 3

| | | Thickness | |
|---|---|---|---|
| | Material | (nanometer) | Refractive index n |
| | semiconductor body | | 2.5 |
| first coating | TiO | 34 | 2.2 |
| first coating | SiO₂ | 148 | 1.5 |
| first coating | TiO | 33 | 2.2 |
| first coating | SiO₂ | 94 | 1.5 |
| first coating | TiO | 98 | 2.2 |
| filling | TiO | 2000 | 2.2 |
| second coating | TiO | 68.6 | 2.2 |
| second coating | SiO₂ | 65.8 | 1.5 |
| second coating | TiO | 23.1 | 2.2 |
| second coating | SiO₂ | 103.6 | 1.5 |
| second coating | TiO | 23.8 | 2.2 |
| | semiconductor body | | 2.5 |

TABLE 4

| | | Thickness | |
|---|---|---|---|
| | Material | (nanometer) | Refractive index n |
| | semiconductor body | | 2.5 |
| first coating | SiO₂ | 24 | 1.5 |
| first coating | TiO | 79 | 2.2 |
| first coating | SiO₂ | 70 | 1.5 |
| first coating | TiO | 54 | 2.2 |
| first coating | SiO₂ | 39 | 1.5 |
| first coating | TiO | 74 | 2.2 |
| first coating | SiO₂ | 157 | 1.5 |
| filling | TiO | 3050 | 2.2 |
| second coating | SiO₂ | 78.5 | 1.5 |
| second coating | TiO | 37 | 2.2 |
| second coating | SiO₂ | 19.5 | 1.5 |
| second coating | TiO | 27 | 2.2 |
| second coating | SiO₂ | 35 | 1.5 |
| second coating | TiO | 39.5 | 2.2 |
| second coating | SiO₂ | 12 | 1.5 |
| | semiconductor body | | 2.5 |

As can be seen in FIG. 10B, with the coating shown in Table 3, where the thickness of the second coating in the region of the second side surface has a ratio of 7:10 to a thickness of the first coating in the region of the first side surface, a similar modulation height and modulation width can be achieved as with the air-filled recess shown in connection with FIGS. 7A, 7B and 9A, but with a significantly smaller recess width. This results in lower coupling losses and thus better laser performance.

As can be seen in FIG. 10C, with the coating indicated in Table 4, in which the thickness of the second coating in the region of the second side surface has a ratio of 1:2 to the thickness of the first coating in the region of the first side surface, a reflectivity of about 75% can be achieved, which would not be possible with purely air-filled recesses. Based on the coatings explained in connection with FIGS. 10B and 10C, it can be seen that any reflectivity can be set with a coating in the recesses.

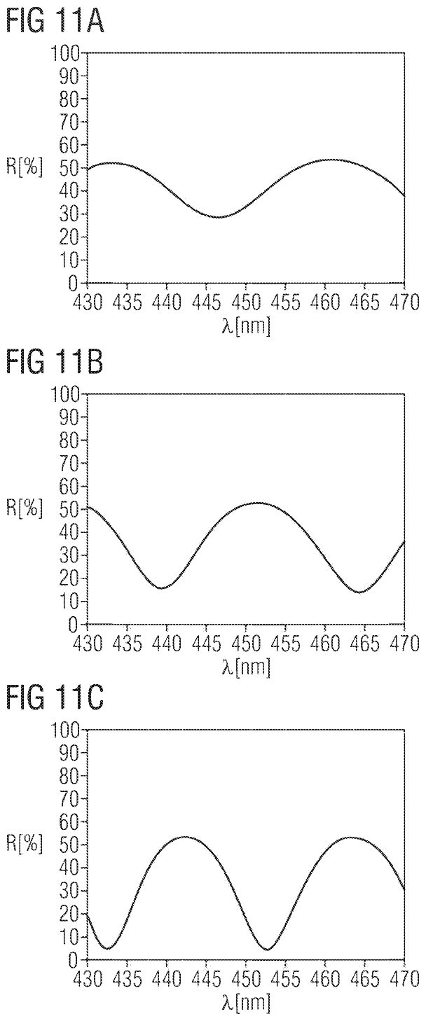

The modulation spacing, i.e. the distance between reflection maxima, can be set, for example, via the refractive index of the filling. The higher the refractive index n of the filling, the smaller the modulation spacing, since this is proportional to λ2/(2×n×B), where B indicates the width of the filling. FIGS. 11A to 11C show this relationship in simulations of reflectivity R as a function of wavelength λ for coatings according to further embodiments with the composition given in Table 5. The refractive index of the filling is n=1.5 (FIG. 11A), n=1.8 (FIG. 11B) and n=2.2 (FIG. 11C). Due to the variation of the refractive index n of the filling, no exemplary material is given for it in Table 5. According to the desired reflectivity, this can be specifically selected by a skilled person. For example, TiO can be selected for the refractive index n=2.2. In this case, the composition of the coating and thus the reflectivity shown in FIG. 11C correspond to the composition of the coating and the reflectivity explained in connection with FIG. 10B. For the refractive indices n=1.5 and n=1.8, for example, SiO2 and SiN can be selected.

TABLE 5

| | | Thickness | |
|---|---|---|---|
| | Material | (nanometer) | Refractive index n |
| | semiconductor body | | 2.5 |
| first coating | TiO | 34 | 2.2 |
| first coating | SiO₂ | 148 | 1.5 |
| first coating | TiO | 33 | 2.2 |
| first coating | SiO₂ | 94 | 1.5 |
| first coating | TiO | 98 | 2.2 |
| filling | | 2000 | n |
| second coating | TiO | 68.6 | 2.2 |
| second coating | SiO₂ | 65.8 | 1.5 |
| second coating | TiO | 23.1 | 2.2 |
| second coating | SiO₂ | 103.6 | 1.5 |
| second coating | TiO | 23.8 | 2.2 |
| | semiconductor body | | 2.5 |

From the dependency λ2/(2×n×B) of the modulation distance it can also be seen that with increasing width of the filling the distance of the reflection maxima becomes smaller. The position of the maxima repeats proportionally to λ/(2×n), and the shift of the maxima with the width B of the filling is proportional to λ/B. Thus, the larger the width of the filling and, consequently, the recess width with a fixed first and second coating, the smaller the shift of the maxima with change of the gap width.

Table 6 shows the structure of the coating reproduced in Table 3. Compared to Table 3, the width B of the filling is given variably.

TABLE 6

| | | Thickness | |
|---|---|---|---|
| | Material | (nanometer) | Refractive index n |
| | semiconductor body | | 2.5 |
| first coating | TiO | 34 | 2.2 |
| first coating | SiO₂ | 148 | 1.5 |
| first coating | TiO | 33 | 2.2 |
| first coating | SiO₂ | 94 | 1.5 |
| first coating | TiO | 98 | 2.2 |
| filling | TiO | B | 2.2 |
| second coating | TiO | 68.6 | 2.2 |
| second coating | SiO₂ | 65.8 | 1.5 |
| second coating | TiO | 23.1 | 2.2 |
| second coating | SiO₂ | 103.6 | 1.5 |
| second coating | TiO | 23.8 | 2.2 |
| | semiconductor body | | 2.5 |

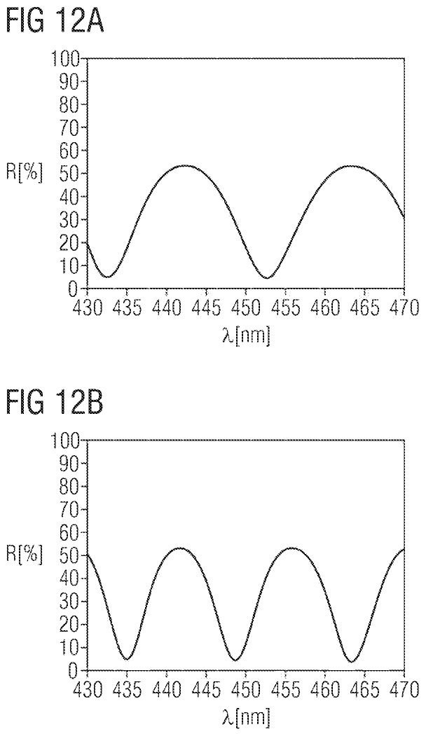

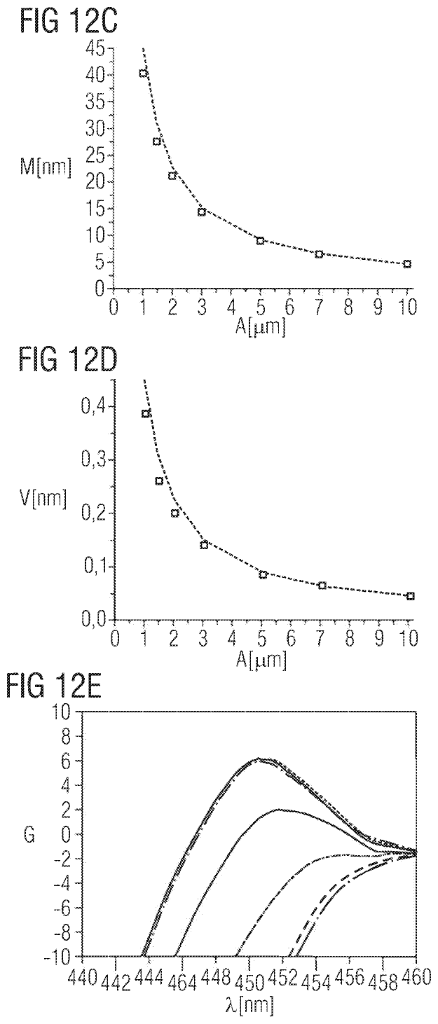

FIGS. 12A and 12B show simulations of the reflectivity R as a function of wavelength λ for the composition given in Table 6 with B=2000 nm and B=3000 nm. Thus, the reflectivity shown in FIG. 12A corresponds to that shown in FIG. 10B.

FIGS. 12C and 12D show simulations for the spacing M of the maxima, i.e. the modulation spacing, and for the shift V of the maxima as a function of the recess width A, while FIG. 12E shows an exemplary simulation of the gain G of a laser diode as a function of the wavelength λ for different operating currents. In the case of a fixed choice of first and second coatings, the aforementioned dependencies on the filling width B apply accordingly also with respect to the recess width A. To force the emitter units to different wavelengths, the distance M between the maxima should be larger than the (half-width) of the gain spectrum, from which it follows that a smaller recess width is advantageous for this purpose. At the same time, the displacement V of the maxima should be as small as possible so that the differences between the emitter units can be adjusted as well as possible and process variations have only a small effect, from which it follows that large recess widths A are advantageous. To keep coupling losses low, the recess width A should in turn be as small as possible. From these boundary conditions, it follows for preferred embodiments that the recess width is greater than or equal to 0.1 nm and less than or equal to 20 μm, preferably greater than or equal to 0.3 nm and less than or equal to 10 μm, and particularly preferably greater than or equal to 0.5 nm and less than or equal to 5 μm.

The features and embodiments described above for the recesses and the coating of the recesses are to be understood as purely exemplary. In particular, depending on the wavelength spectrum and technical requirements of the light-emitting semiconductor chip, materials, layer thicknesses, layer combinations, fillings, recess widths and recess positions can be specifically adapted.

In connection with the following figures, further embodiments for the construction of the light-emitting semiconductor chip and in particular of the emitter units are shown, which represent modifications of the embodiments described above.

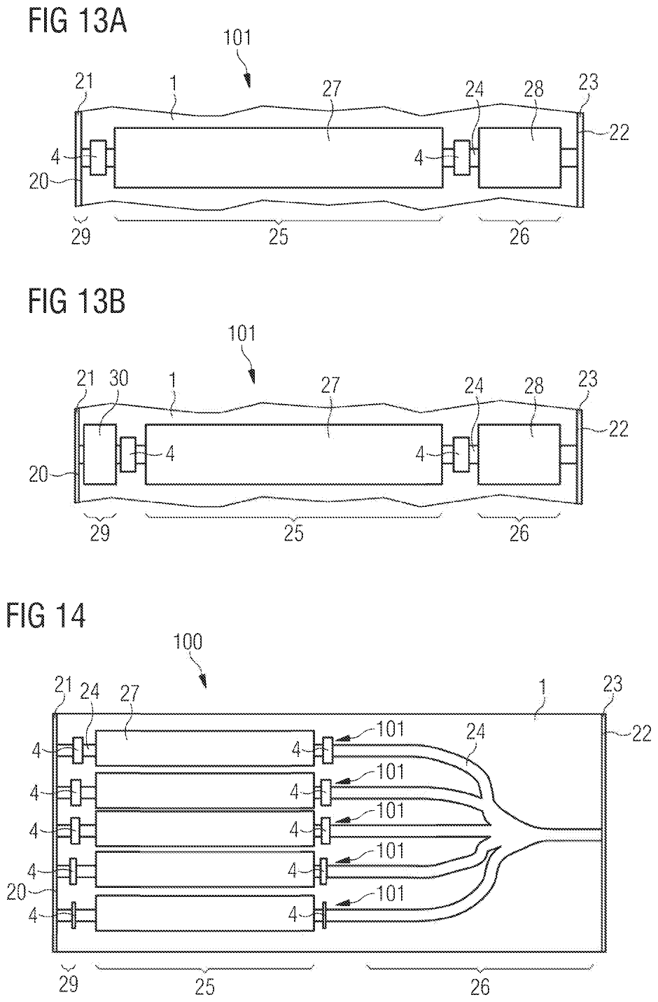

FIGS. 13A and 13B show emitter units 101 for a light-emitting semiconductor chip having two recesses 4, one of which is formed in the region of the rear side 20 and the other of which is formed in the region of the outcoupling side 22. Thus, the shown emitter units 101 each have a first segment 25 forming the light-generating part, a second segment 26 in the region of the outcoupling side 22, which may be formed, for example, as described in connection with FIGS. 8A and 8B, and a third segment 29 in the region of the rear side 29. For the emitter unit 101 shown in FIG. 13A, the rear-side third segment 29 may be formed as an uncontacted and thus passive segment as described in connection with FIGS. 1A to 2B, while the rear-side third segment 29 for the emitter unit 101 shown in FIG. 13B may be formed as an active segment as described in connection with FIGS. 6A and 6B, comprising a third electrical contact point 30, for example an electrode layer. In particular, for example, the recess 4 in the region of the rear side 20 may form a rear side mirroring and the recess 4 in the outcoupling side region 22 may form an outcoupling mirroring for the resonator formed by the first segment 25. The first and second layers 21, 23 can be formed with as little reflection as possible. The recesses 4 in the region of the rear side 20 and the recesses 4 in the region of the outcoupling side 22 can be formed as in the embodiments described above and, in particular, each have different recess widths, as can also be seen in the figures in connection with the following embodiments. The recesses 4 associated with a same emitter unit 101 may be formed identically or differently with respect to dimensions and/or a coating.

By combining multiple recesses 4 per emitter unit 101 such as the one shown in FIGS. 13A and 13B, modulation effects can be enhanced and/or narrower reflection maxima can be achieved. For example, superposition effects can also be achieved by different formations of the recesses with respect to the recess width and the coating. Since the maxima of the respective reflection spectra have a certain spectral width, a significantly narrower wavelength window in which the emitter unit 101 must emit can be achieved by two spectra that are slightly shifted with respect to each other in the region of the outcoupling side and in the region of the rear side. If the formations of the recesses in the region of the outcoupling side and in the region of the rear side are different, multiple wavy spectra can be generated, for example. On the other hand, if the formations of the recesses in the region of the outcoupling side and in the region of the rear side are the same, amplification of the modulation can be achieved. As an alternative to the embodiments shown, other combinations with one, two or more active and/or passive segments can also be possible by means of a suitable number and arrangement of recesses.

The embodiment for the light-emitting semiconductor chip 100 shown in FIG. 14 again has, purely by way of example, two recesses 4 per emitter unit 101 for subdivision into three segments 25, 26, 29, the ridge waveguide structure 24 in the second region 26 being designed as a waveguide and combiner. The light-emitting semiconductor chip 100 may thus be formed as a photonically integrated laser device. As an alternative to the passively formed third segments 29, these may also be formed here and also in the following embodiments, for example, as an integrated photodiode and thus formed as an active segment, as described further above.

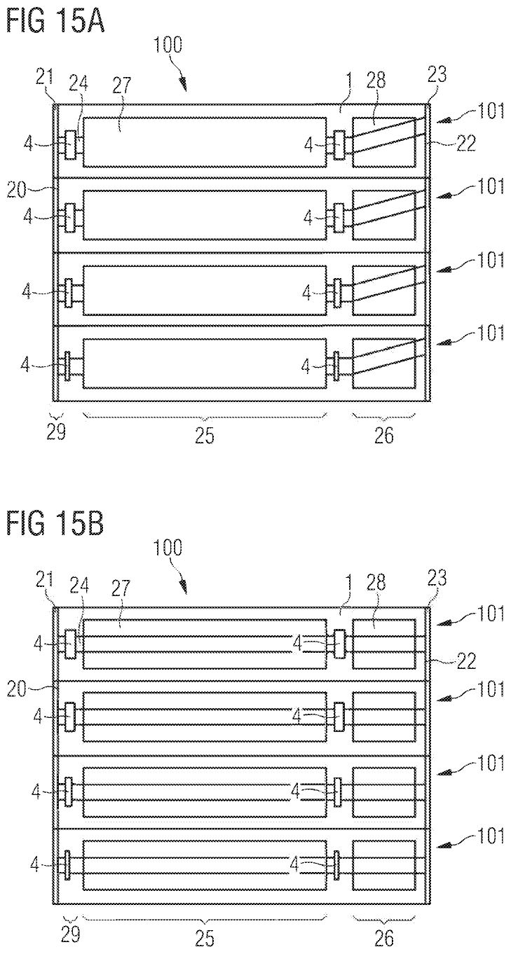

In the embodiments of the light-emitting semiconductor chip 100 shown in FIGS. 15A and 15B, the ridge waveguide structures 24 of the emitter units 101 in the second segment 26 each have a slope (FIG. 15A) or a curvature (FIG. 15B), which may result in super luminescent behaviour. Thus, the light-emitting semiconductor chips 100 shown in FIGS. 15A and 15B may be super luminescent diodes.

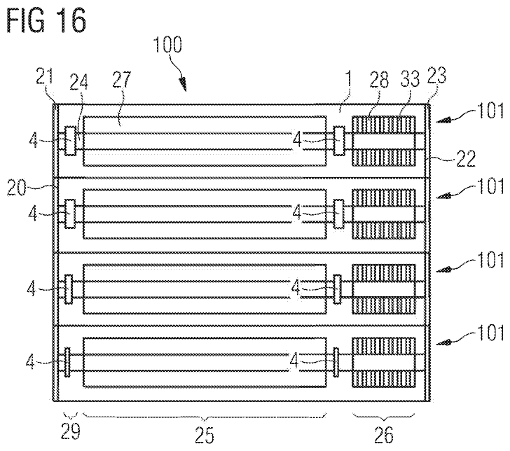

FIG. 16 shows a further embodiment of the light-emitting semiconductor chip 100 in which a wavelength selective element 33, for example a type of grating such as a distributed feedback laser (DFB) structure, is provided in the second segment 26 of each of the emitter units 101. The wavelength selective element 33 may be formed, for example, on the side of the ridge waveguide structure 24 and/or on and/or over and/or in the ridge waveguide structure 24.

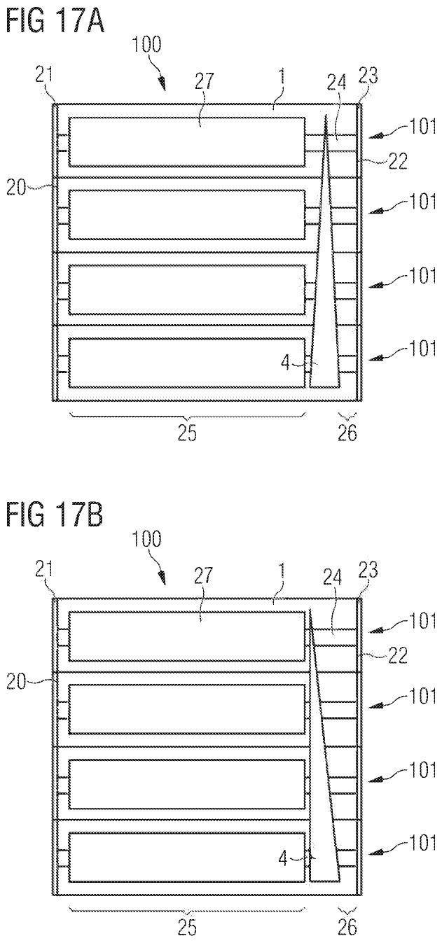

In the embodiments described above, each emitter unit 101 of the light-emitting semiconductor chip 100 has at least one dedicated recess 4, each of which is separate from all other recesses 4 in the semiconductor body 1. Alternatively, there may be at least one recess 4 in the semiconductor body 1 that extends through the active regions of a plurality, and preferably all, of the emitter units 101, as shown in FIGS. 17A and 17B. Thus, the recess 4 may be designed as a continuous slit or gap with changing recess width. Advantageously, at least one side surface of the recess may be oriented perpendicular to the emission direction of the generated light. In the embodiments shown, all active regions of the light-emitting semiconductor chip 100 are each penetrated by a single recess 4. In order for the recess widths for the emitter units 101 to differ, the recess 4 may have a base surface with a double-sided or single-sided wedge shape, as indicated in FIGS. 17A and 17B. Accordingly, one or both side surfaces of the recess 4 may be partially oblique to the main direction of extension of the recess 4. Alternatively or additionally, an at least partially curved and/or stepped course of one or both side surfaces is also possible.

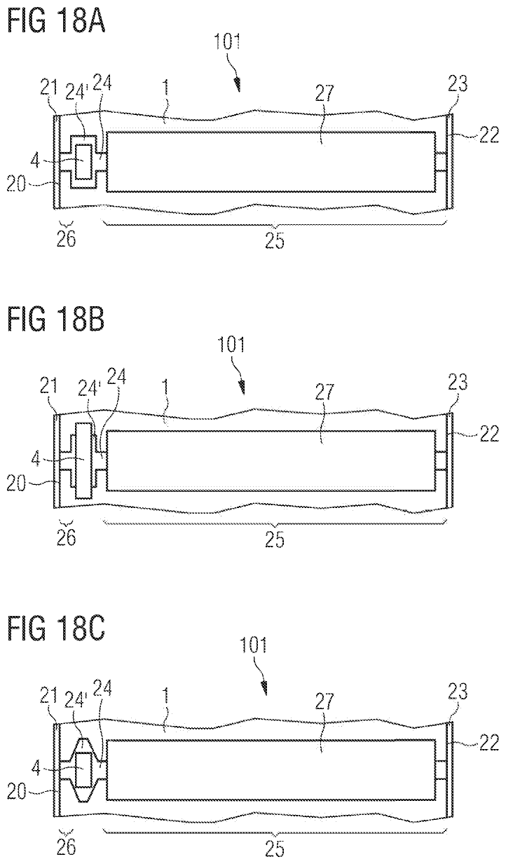

As shown in the previous embodiments, the ridge waveguide structures 24 may be designed, for example, as strips of constant width interrupted by the at least one recess 4. To achieve a better facet quality, the ridge waveguide structures 24 may also have a thickening 24′ in the region of the at least one recess 4 in the form of a widening along the main extension direction of the at least one recess 4, as indicated in FIGS. 18A to 18C. The at least one recess 4 may be located within the widening 24′ (FIG. 18A), it may be of the same width as the widening 24′ (not shown), or it may project beyond the widening 24′ along the main extension direction of the recess 4 (FIG. 18B). The thickening 24′ may be rectangular, as indicated in FIGS. 18A and 18B. It may also be advantageous if the ridge waveguide structure 24 gradually widens towards the recess 4 (FIG. 18C), which may also be referred to as a so-called taper, in order to reduce coupling losses.

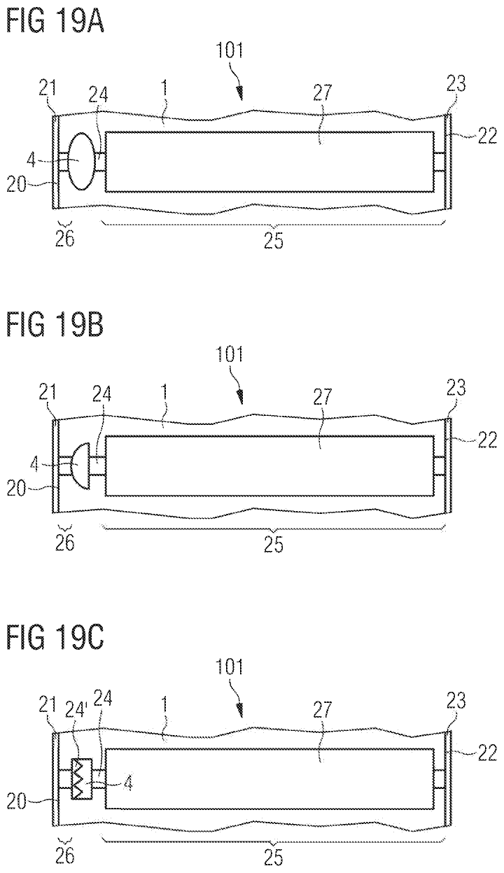

To reduce coupling losses, the at least one recess 4, as indicated in FIGS. 19A to 19C, can also have round or convex or concave shapes on one or both sides instead of a rectangular basic shape. Purely by way of example, a shape that is convex on one side and a shape that is convex on both sides are shown in FIGS. 19A and 19B. The at least one recess 4 can also have more complex shapes, for example that of a retroreflector (cat's eye), as indicated in FIG. 19C.

The features and embodiments described in connection with the figures can be combined with each other according to further embodiments, even if not all combinations are explicitly described. Furthermore, the embodiments described in connection with the figures may alternatively or additionally have further features according to the description in the general part.

The invention is not limited by the description based on the embodiments to these embodiments. Rather, the invention includes each new feature and each combination of features, which includes in particular each combination of features in the patent claims, even if this feature or this combination itself is not explicitly explained in the patent claims or embodiments.

1-20. (canceled)

21. A light-emitting semiconductor chip comprising:
a semiconductor body comprising a plurality of emitter units,
wherein each emitter unit comprises an active region which is arranged in a resonator having an outcoupling side and a rear side and which is configured to emit light at the outcoupling side along a radiation emission direction,
wherein, in each emitter unit, the active region is completely penetrated by at least one recess in the semiconductor body,
wherein, in each emitter unit, in a region of the active region the recess has a recess width measured along the radiation emission direction, and
wherein recess widths of the emitter units are at least partially different.

22. The light-emitting semiconductor chip of claim 21, wherein the recess widths of the emitter units differ by an amount that is greater than or equal to 1 nm and less than or equal to 2 μm.

23. The light-emitting semiconductor chip according to claim 21, wherein at least three emitter units are present and the recess widths of the emitter units differ equidistantly from each other.

24. The light-emitting semiconductor chip according to claim 21, wherein each emitter unit has at least one recess that is separate from the recesses of other emitter units.

25. The light-emitting semiconductor chip according to claim 21, wherein the at least one recess extends through active regions of two or more emitter units.

26. The light-emitting semiconductor chip according to claim 25, wherein the recess width of the at least one recess increases continuously or stepwise from emitter unit to emitter unit.

27. The light-emitting semiconductor chip according to claim 21, wherein the at least one recess has a rectangular base surface or an at least partially wedge-shaped and/or at least partially rounded base.

28. The light-emitting semiconductor chip according to claim 21, wherein, for each emitter unit, the semiconductor body comprises a ridge waveguide structure, and wherein the ridge waveguide structure comprises, in the region of the at least one recess, a thickening along a main extension direction of the at least one recess.

29. The light-emitting semiconductor chip according to claim 21, wherein, for each emitter unit, at least one recess is arranged in a region of the rear side.

30. The light-emitting semiconductor chip according to claim 21, wherein, for each emitter unit, at least one recess is arranged in a region of the outcoupling side.

31. The light-emitting semiconductor chip according to claim 21, wherein, for each emitter unit, the active region is completely penetrated by at least two recesses, and wherein one of the recesses is arranged in the region of the rear side and another of the recesses is arranged in the region of the outcoupling side.

32. The light-emitting semiconductor chip according to claim 21, wherein, for each emitter unit, the at least one recess has at least one coating specifying a reflectivity of the recess for the light generated in the active region, the reflectivity being less than or equal to 99.9% and greater than or equal to 80%.

33. The light-emitting semiconductor chip according to claim 21, wherein, for each emitter unit,
the at least one recess has, in the radiation emission direction, a first side surface and a second side surface opposite the first side surface, and
the first side surface has a first coating which provides a reflectivity for the light generated in the active region and which is formed as a first layer sequence with a plurality of individual layers, and/or
the second side surface has a second coating which provides a reflectivity for the light generated in the active region and which is formed as a second layer sequence with a plurality of individual layers.

34. The light-emitting semiconductor chip according to claim 33, wherein the first coating and the second coating are embodied differently from each other.

35. The light-emitting semiconductor chip according to claim 34, wherein a thickness of the first coating in the region of the first side surface to a thickness of the second coating in the region of the second side surface has a ratio between 1:1 and 1:20, inclusive.

36. The light-emitting semiconductor chip according to claim 32, further comprising a filling in the recess.

37. The light-emitting semiconductor chip according to claim 21, wherein each emitter unit comprises a first segment and a second segment, the first segment being electrically and/or optically isolated from the second segment by the at least one recess.

38. The light-emitting semiconductor chip according to claim 37, wherein, for each emitter unit, the first segment comprises a light generating part and the second segment comprises a modulating element configured to modulate an intensity of the light of the active region.

39. The light-emitting semiconductor chip according to claim 21, wherein at least one of the emitter units comprises a segment comprising one or more of a photodiode, a passive waveguide, an active waveguide, a beam splitter, a beam combiner, a lens, a wavelength selective element, phase shift elements, a frequency doubler, a taper, an amplifier, a converter or a transistor.

40. A method for manufacturing the light-emitting semiconductor chip according to claim 21, the method comprising:
producing the semiconductor body; and
producing the at least one recess in the semiconductor body.
